(19) United States
(12) Patent Application Publication
(10) Pub. No.: US 2026/0040543 A1
(43) Pub. Date: Feb. 5, 2026

(54) eFlash cell array using Metal capacitor

(71) Applicant: ANAFLASH INC., Sunnyvale, CA (US)

(72) Inventor: Sihwan Kim, San Francisco, CA (US)

(21) Appl. No.: 19/228,675

(22) Filed: Jun. 4, 2025

Related U.S. Application Data
(60) Provisional application No. 63/679,123, filed on Aug. 4, 2024.

(51) Int. Cl. H10B 41/70; G11C 16/04; H10B 41/35

(52) U.S. Cl. CPC H10B 41/70; G11C 16/0441; H10B 41/35

(57) ABSTRACT

A nonvolatile memory unit cell can comprises: a P-type substrate; a set of one or more P-type transistors with floating gates, each having an active drain and source region on an N-well doped on the P-type substrate; one N-type transistor sharing the floating gate of the one or more P-type transistors, with active drain and source regions doped on the P-type substrate; a polysilicon layer above the gate regions of the P-type and N-type transistors; a plurality of control lines to apply voltages to the gates, source, and drains of the transistors; and a plurality of metal layers above the polysilicon layer, wherein a main metal layer (1) is configured with a plurality of metal plates spaced apart with one or more intervals forming a parallel-plate structure in a lateral direction and (2) forms a parallel plate structure in a horizontal direction with at least one parallel metal layer.

### CROSS-REFERENCE TO RELATED APPLICATIONS

This application claims priority to and the benefit of Provisional U.S. Patent Application No. 63/679,123, filed on Aug. 4, 2024.

### TECHNICAL FIELD OF THE INVENTION

The subject matter disclosed herein generally relates to the field of embedded non-volatile flash memory devices, and more specifically to the structure of a new non-volatile flash memory device using metal capacitors, which can serve as an alternative to conventional logic-compatible embedded non-volatile flash memory devices that rely solely on CMOS transistors.

### BACKGROUND OF THE INVENTION

Embedded flash memory (eFlash memory) is a type of non-volatile memory that is integrated directly into a system, often a microcontroller or System-on-Chip (SoC). Unlike removable flash storage devices, such as USB drives or SD cards, embedded flash is integrated within the device and cannot be easily removed. In eFlash, the flash memory cells are fabricated directly alongside the processor, analog circuits, and other digital logic on a single piece of silicon. This embedded flash memory's technical merits can be summarized as follows:

As eFlash is embedded on the same chip, it can eliminate the need for external bus communication, leading to significantly faster read and write access times. This is crucial for applications that require code execution directly from memory. Additionally, as eFlash memory can be integrated onto the System-on-Chip (SoC), it can save valuable board space, allowing for smaller and more compact devices. Additionally, eFlash can simplify system design, reduce bill of materials (BOM) costs, and enhance overall system reliability by utilizing fewer discrete components. Due to these technical merits, eFlash is widely used in applications where a microcontroller or SoC needs to store its firmware, operating system, or critical configuration data directly on the chip for fast access and reliable operation.

Flash memory cells are made of floating-gate transistors. Data is stored by trapping or releasing electrons in the floating gate, which changes the electrical charge and represents a binary state (0 or 1). An electrical charge is applied to the floating gate to program (write) data, and a higher voltage is applied to erase data by removing the trapped electrons

Flash memory is a type of nonvolatile memory that can store information permanently even when the system power is off. Logic-compatible flash memory is a type of flash memory built using only logic devices. Memory with a floating gate structure has been used as a logic-compatible flash memory. In memory utilizing a floating gate structure, electrons are injected into the floating gate during the program operation. During the read operation, the stored data can be recognized by sensing changes in the current flowing through the memory cell due to the electrons trapped in the floating gate.

In logic-compatible flash memory devices, the floating gate transistor is the fundamental building block that allows for non-volatile data storage. The key is that the floating gate is electrically isolated, meaning the charge placed on it remains there even when power is removed. This charge represents the stored bit (0 or 1). Data is written (programmed) using a process called hot-electron injection or Fowler-Nordheim tunneling. A high voltage is applied between the control gate and the source/drain. This forms a strong electric field that accelerates electrons from the channel region.

Some of these high-energy electrons tunnel through the thin oxide layer and become trapped in the isolated floating gate. The number of trapped electrons represents the stored bit. Specifically, Logic 1 is the status where a sufficient number of electrons are injected into the floating gate, creating a significant negative charge. This charge influences the channel, raising the threshold voltage of the connected transistor and causing a smaller current to flow through the transistor when the read voltage is applied compared to when electrons are not trapped in the floating gate.

Logic 0 is the status where few or no electrons are injected. The floating gate remains essentially neutral. Since the transistor has an intrinsic threshold voltage, a larger current flows through the transistor when the read voltage is applied compared to when electrons are trapped in the floating gate. The process needs precise voltage control to ensure the correct number of electrons are injected for reliable data storage. Logic compatibility here means the programming voltage is higher than the typical logic voltage levels, but still within a range that is manageable with standard semiconductor fabrication processes.

As semiconductor manufacturing processes shrink to smaller nodes (e.g., below 28 nm), integrating traditional floating-gate based eFlash becomes increasingly challenging and costly due to the complex manufacturing steps it adds to a logic process as described above.

More precisely, conventional logic-compatible flash memory, designed for integration with logic circuits, typically uses smaller transistors and thinner oxides to increase density and performance. In this setup, among the transistors sharing a floating gate, one transistor requires a significantly larger width compared to the others to achieve a dominant effect when high voltage is applied during programming. In one example, the transistor dominant for high voltage has a width that is eight times larger than the coupled transistor. A transistor with a larger width can increase macro area when implementing high-density embedded non-volatile flash memory. As memory density increases, this issue will become more severe, necessitating a new memory structure that can replace conventional logic-compatible flash memory designs.

To address these critical challenges in the design of logic-compatible flash memory, this invention proposes a new structure for logic-compatible flash memory utilizing metal capacitors as an alternative to conventional floating gate memory.

### SUMMARY OF INVENTION

The present invention has been made in view of the above difficulties and problems. A primary objective of the present invention is to provide an efficient design for the array of unit memory cells. Non-volatile memory cells based on floating gates can be efficiently arranged on semiconductor substrates according to the following specification. The present invention describes various configurations of component transistors within each non-volatile memory cell on a semiconductor die, thereby reducing the overall die size.

According to example embodiments of the inventive concepts, a nonvolatile memory unit cell may include a P-type substrate; a set of one or more P-type transistors with floating gates that store a charge, each having an active drain and source region on an N-well doped on the P-type substrate; one N-type transistor sharing the floating gate of the one or more P-type transistors, with active drain and source regions doped on the P-type substrate; a polysilicon layer above the gate regions of the P-type and N-type transistors; a plurality of control lines as electrical pathways used to apply voltages to the gates, source, and drains of the transistors for operation, including a programming word line; and a plurality of metal layers deposited above the polysilicon layer, wherein a main metal layer is configured with a plurality of metal plates that are spaced apart with one or more predefined intervals forming a parallel-plate structure in a lateral direction; and wherein the main metal layer forms a parallel plate structure in a horizontal direction with at least one parallel metal layer, which is directly facing the main metal layer and separated from the main metal layer by a dielectric insulating layer.

In some example embodiments, the main metal layer is placed between a pair of parallel metal layers and insulated by dielectric insulating layers that separate the main metal layer from each of the pair of parallel metal layers.

In some example embodiments, a number of the set of one or more P-type transistors is determined based on capacitance created by the main metal layer and the at least one parallel metal layer.

In some example embodiments, the set of P-type transistors with floating gates consists of a pair of P-type transistors and a size of the active drain/source regions of a first transistor of the pair of P-type transistors is determined based on the capacitance created by the main metal layer and the at least one parallel metal layer.

In further example embodiments, the polysilicon layer is (1) a layer of polycrystalline silicon as gate material of the one or more P-type transistors and the N-type transistor and (2) electrically insulated from the active regions of the one or more P-type transistors and the N-type transistor by a tunnel oxide with predefined thickness.

In further example embodiments, a first of the pair of parallel metal layers is a metal plate parallel to the polysilicon layer in a horizontal direction of the memory unit cell and spaced apart and isolated from the polysilicon layer by a first interlayer dielectric with predefined thickness.

In further example embodiments, a length of the first parallel metal layer is determined based on an area of the one or more P-type transistors on the N-well doped on the P-type substrate and the N-type transistor in a horizontal direction of the memory unit cell.

In further example embodiments, the first parallel metal layer further comprises one or more vias connecting the first parallel metal layer to the polysilicon layer.

In further example embodiments, the main metal layer is spaced apart and isolated from the first parallel metal layer by a second interlayer dielectric with predefined thickness.

In further example embodiments, the main metal layer further comprises the programming word line with a horizontal width allowing each programming word line to be placed between a pair of the metal plates, forming the parallel-plate structure to create capacitance in the lateral direction.

In further example embodiments, a gap between the metal plate and the programming word line is filled with a standard intermetal dielectric.

In further example embodiments, the main metal layer further comprises a first group of vias connecting the main metal layer to the first parallel metal layer.

In further example embodiments, a second of the pair of parallel metal layers is a metal plate parallel to the main metal layer and spaced apart from the main metal layer by a third interlayer dielectric with predefined thickness, forming a parallel plate structure between the second parallel metal layer and the one or more programming word line.

In further example embodiments, the main metal layer further comprises a second group of vias connecting the main metal layer to the second parallel metal layer.

In further example embodiments, the nonvolatile memory unit cell further includes a pair of N-type select transistors connected to the N-type transistor in series.

In further example embodiments, a first of the pair of N-type select transistors has a gate directly connected to a read word line (RWL) and a second of the pair of N-type select transistors has a gate directly connected to an erase word line (EWL).

In further example embodiments, the first N-type select transistor has a drain directly connected to a bit line (BL) and the second N-type select transistor has a source directly connected to a common source line (CSL) for carrying a signal for operating the nonvolatile memory unit cell.

In further example embodiments, the first N-type select transistor and the N-type transistor share a common active drain/source region and the second N-type select transistor and the N-type transistor share a common drain/source region.

While example embodiments have been particularly shown and described, it will be understood by one of ordinary skill in the art that variations in form and detail may be made therein without departing from the spirit and scope of the claims.

### BRIEF DESCRIPTION OF THE DRAWINGS

The following drawing parts of the specification are included to further demonstrate certain embodiments or various aspects of the invention. In some instances, embodiments of the invention can be best understood by referring to the accompanying drawings in combination with the detailed description presented herein. The description and accompanying drawings may highlight a certain specific example, or a certain aspect of the invention. However, one skilled in the art will understand that portions of the example or aspect may be used in combination with other examples or aspects of the invention.

FIG. 1 shows a schematic diagram of a traditional logic-compatible 5T eFlash memory unit cell;

FIG. 2 illustrates a 3D layout perspective view of a traditional eFlash memory unit cell;

FIGS. 3A-3D are cross-sectional views of transistors M1, M2, and M3 in a traditional 5T eFlash memory unit cell;

FIG. 4 shows a vertical cross-sectional diagram illustrating an arrangement of multiple metal layers for creating capacitance according to example embodiments of the present invention;

FIG. 5 shows a schematic of 5T eFlash memory unit cell using metal capacitor according to example embodiments of the present invention;

FIGS. 6A-6D are cross-sectional diagram illustrating transistors M1, M2, and M3 in a proposed 5T eFlash memory unit cell with the metal capacitors according to example embodiments of the present invention;

FIG. 7 shows a proposed 4T eFlash memory unit cell schematic using metal capacitor according to example embodiments of the present invention;

FIGS. 8A-8B are cross-sectional diagram illustrating transistors M2 and M3 in a proposed 4T eFlash memory unit cell with the metal capacitors according to example embodiments of the present invention.

### DETAILED DESCRIPTION OF THE INVENTION

In the following detailed description of the invention, reference is made to the accompanying drawings that form a part hereof, which is shown by way of illustration and specific embodiment. In the drawings, like numerals, features of the present invention will become apparent to those skilled in the art from the following description of the drawings. Understanding that the drawings depict only typical embodiments of the invention and are not, therefore, to be considered limiting in scope, the invention will be described with additional specificity and detail through the accompanying drawings.

In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

It will be understood that although the terms first and second are used herein to describe various regions, layers and/or sections, these regions, layers and/or sections should not be limited by these terms. These terms are only used to distinguish one region, layer or section from another region, layer or section. Thus, a first region, layer or section discussed below could be termed a second region, layer or section, and similarly, a second region, layer or section may be termed a first region, layer or section without departing from the scope of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

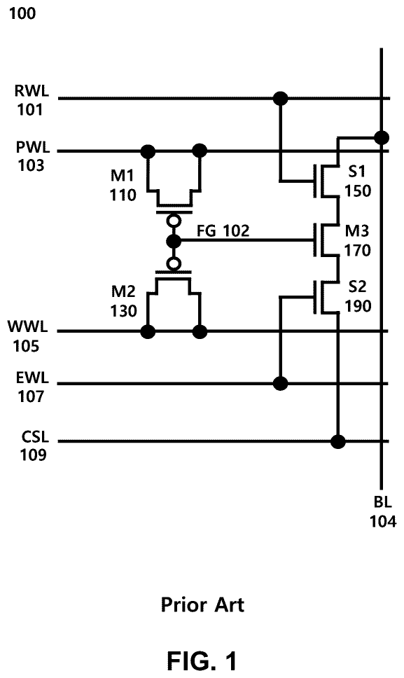

FIG. 1 shows a schematic of a logic-compatible 5T (five transistors) eFlash memory unit cell 100. Additional details about the analysis and operation of the memory unit cell are described in U.S. application Ser. No. 16/196,617, filed Nov. 20, 2018, now U.S. Pat. No. 11,361,215 to Anaflash Inc, “Neural Network Circuits Having Non-Volatile Synapse Arrays.”

As regards the operation of the flash memory unit cell 100, all five transistors M1 110, M2 130, M3 170, S1 150, S2 190 are implemented using standard I/O transistors. The transistor M1 110 is a coupling transistor, M2 130 is an erase transistor, M3 170 is a program/read transistor, and S1 150 and S2 190 are selection transistors for the program inhibition operation. The memory unit cell 100 is connected in the row direction to a program word line (PWL 103), a read word line (RWL 101), a write word line (WWL 105), an erase word line (EWL 107), and a common source line (CSL 109). Additionally, the memory unit cell 100 is connected in the column direction to a bit line (BL 104).

A floating gate FG 102 in the memory unit cell 100 is capacitively coupled to transistors M1 110 and M2 130. Thus, the memory unit cell 100 can store data in the form of a threshold voltage, which is the lowest voltage at which the memory unit cell 100 can be switched on. The threshold voltage is controlled by the amount of charge retained on the floating gate FG 102. The gates of the PMOS transistors M1 110 and M2 130 are connected to FG 102, while their drain and source are connected to PWL 103 and WWL 105, respectively. The program/read transistor, M3 170, has its gate connected to the FG 102, its drain connected to the source of the S1 150 transistor, and its source connected to the drain of the S2 190 transistor. The drain of the S1 150 transistor is connected to the bit line (BL 104), and its gate receives the RWL 101 signal. The gate of the S2 190 transistor receives the EWL 107 signal, and its source is connected to the CSL 109.

The floating gate FG 102 can store two or more than two states. In the case of two states, the memory unit cell 100 can be either programmed or erased. When the memory unit cell 100 is in the fully erased state, only a small number of electrons are trapped in the floating gate FG 102; therefore, the memory unit cell 100 allows a large amount of current to flow during the read operation. Conversely, when the memory unit cell 100 is in the fully programmed state, a large number of electrons are stored in the FG 102; therefore, the memory unit cell 100 allows only a small amount of current to flow during the read operation.

During the read operation, a read voltage is applied to the PWL 103 and WWL 105, while VDD is applied to the RWL 101 and EWL 107 to turn on the selection transistors (S1 150, S2 190). Additionally, the CSL 109 is grounded, and a bit line voltage is applied to the BL 104. With these voltages applied, the amount of current flowing through the BL 104 varies depending on the number of electrons stored in the FG 102 of the memory unit cell 100, allowing the data stored in the memory cell 100 to be read.

For the program operation, a high program voltage HV (about 4 times of VDD) is applied to the PWL 103 and WWL 105, and the supply voltage VDD is applied to the RWL 101 and the CSL 109. The ground level is applied to the EWL 107. To program the memory unit cell 100, the selection transistor S1 150 is set to be turned on, the BL 104 is grounded, and the supply voltage VDD is applied to the RWL 101 which is connected to a gate of the selection transistor S1 150. As a result, the selection transistor S1 150 is biased in a conductive state (i.e., “on”). The other selection transistor S2 190 is turned off by grounding the gate of the transistor, the EWL 107. Then, a voltage difference between a floating gate FG 102 and an electron channel of the program/read transistor M3 170 becomes sufficiently high when the HV is applied to the PWL 103 and WWL 105. Consequently, the electrons are injected into the floating gate FG 102 by Fowler-Nordheim tunneling, and when electrons accumulate there, the FG 102 is negatively charged, then the threshold voltage of the memory unit cell 100 is raised. The threshold voltage of the memory unit cell 100 is indicative of a programmed state in response to the stored electrons.

The erase operation performed by removing electrons from the floating gate FG 102 of the unit memory cell 100. During the erase operation, a positive high voltage HV is applied to the WWL 105 and a ground voltage is applied to the RWL 101, PWL 103, EWL 107, CSL 109, and BL 104. Since a ground voltage is applied to the gates of selection transistors S1 150 and S2 190, turning the transistors off, no current flows through S1 150, M3 170, and S2 190. The coupling transistor M1 110, to which the source and drain are connected to PWL 103, is significantly larger in size than the erase transistor M2 130, to which the source and drain are connected to WWL 105. Thus, the ground voltage applied to the source and drain of transistor M1 110 causes the FG 102 node voltage potentials close to the ground voltage potential. Consequently, the voltage difference between the voltage of WWL 105 and this nearly grounded voltage potential of the FG 102 is sufficient to repel the trapped negative charges inside the FG 102 through the erase transistor M2 130.

Transistors M2 130, M3 170, S1 150, and S2 190 are typically designed with a minimum length (L) and width (W) to minimize the size of the eFlash memory unit cell 100 when implemented on a semiconductor substrate. However, as described above, M1 110, which is the coupling transistor that tightly controls the FG 102 with a high coupling ratio, has a much bigger width or length compared to transistors M2 130, M3 170, S1 150, and S2. For example, in some embodiments, the width of transistor M1 110 is 8 times larger than that of other transistors. Thus, the significantly larger size of transistor M1 110 compared to other transistors can increase macro area when implementing high-density embedded non-volatile flash memory.

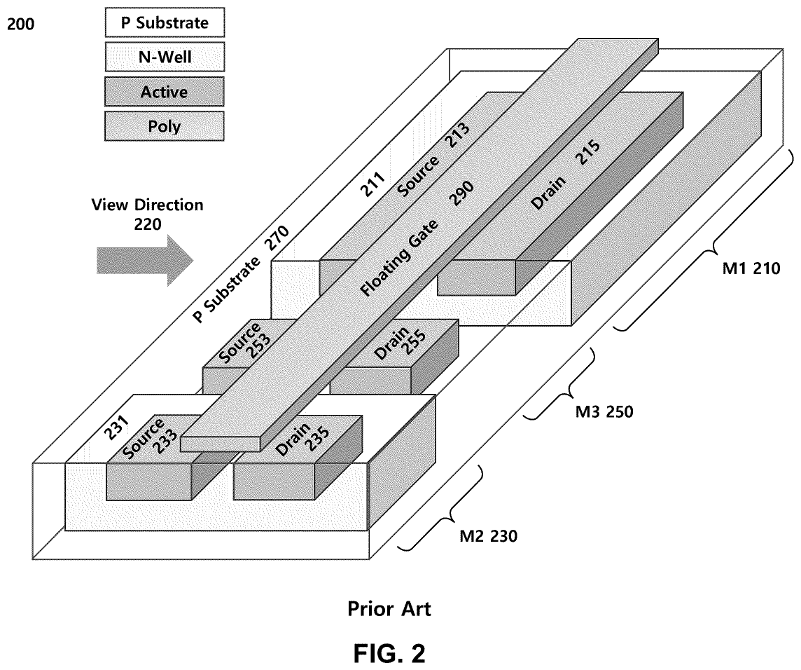

FIG. 2 shows a 3D layout perspective view 200 of a traditional eFlash unit memory cell. FIG. 2 illustrates a perspective view of a layout that is conventionally used when implementing an eFlash unit memory cell 100 using MOSFETs on a semiconductor substrate.

Additional details about the structure of the metal layers of the memory unit cell are described in U.S. application Ser. No. 18/200,199, filed Mar. 22, 2023 to Anaflash Inc., “Nonvolatile Memory Unit Cell and Array Architecture.” To help clarify and better understand the subsequent figures, FIG. 2 shows the layout of transistors M1 210, M2 230, and M3 250 among the components of the traditional logic-compatible 5T eFlash memory unit cell 100 illustrated in FIG. 1. However, the layouts of transistors S1 150 and S2 190 have been omitted.

The transistors M1 210, M2 230, and M3 250 are implemented on a P-substrate 270. Since transistors M1 210 and M2 230 are PMOS transistors, they are formed on N-wells 211 and 231, respectively, provided within the P-substrate 270. The transistor M1 210 includes a source 213 and a drain 215 formed in the N-well 211, while the transistor M2 230 includes a source 233 and a drain 235 formed in the N-well 231. The transistor M3 250 is an NMOS transistor and therefore has a source 253 and a drain 255 formed directly in the P-substrate 270. A floating gate 290, formed of a polysilicon layer, extends over the gate regions of transistors M1 210, M2 230, and M3 250. The indicated view direction 220 corresponds to the viewing direction for the cross-sectional layout views provided in the subsequent figures.

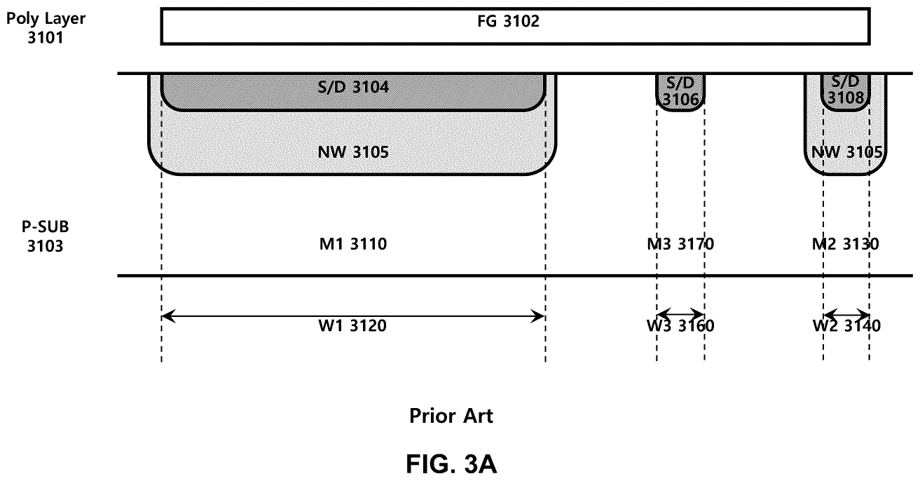

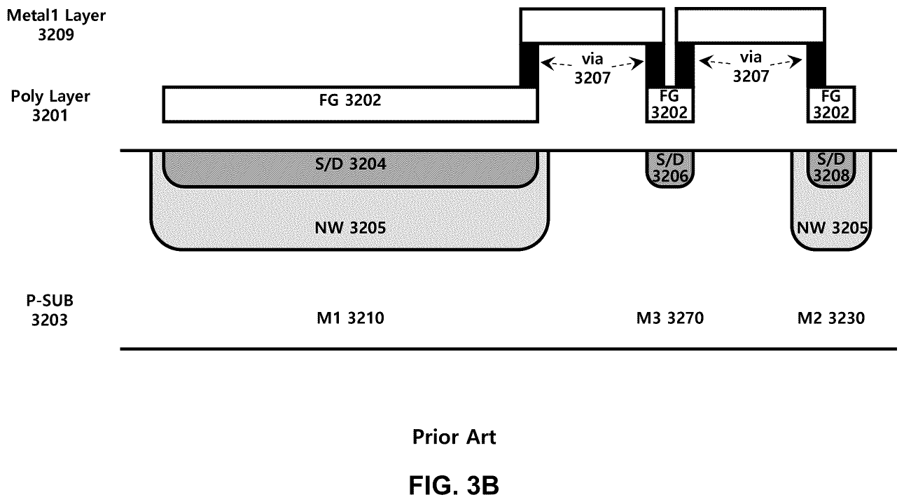

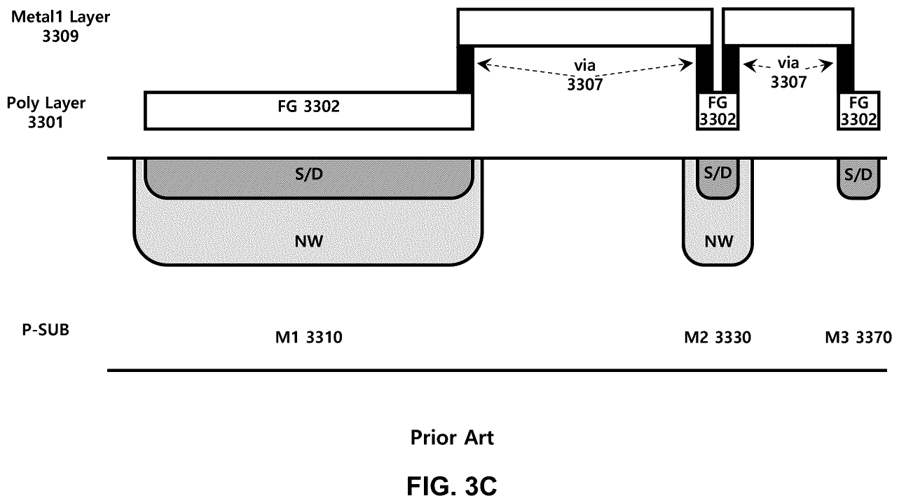

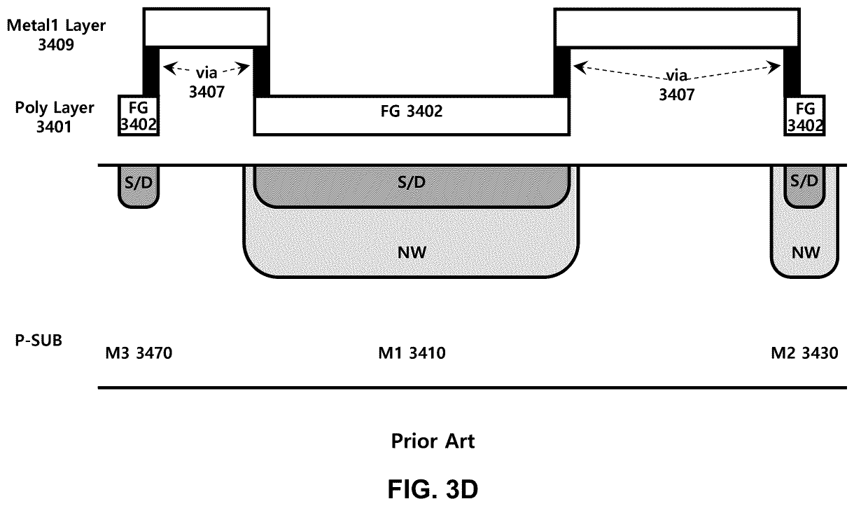

FIGS. 3A-3D show cross-sectional views in the view direction 220 of transistors M1 210, M2 230, and M3 250 sharing the Floating Gate 290 in traditional 5T eFlash memory unit cell 200 implemented on an actual semiconductor substrate. Transistors S1 150 and S2 190 (not shown), which do not share the Floating Gate 290 with transistors M1 210, M2 230, and M3 250, can be placed anywhere around transistors M1-M2-M3.

FIG. 3A shows a typical example of transistor M1-M3-M2 structure connecting floating gate FG 3102 with Polysilicon layer 3101. FG 3102 is isolated from any other layers such as metal layers or active layers (source/drain), which enables holding electrons to control the threshold voltage of the program/read transistor (M3 3170). PWL and WWL have word line (WL) direction metal connections (not shown) to tie the source, drain, and body (N-well) of transistor M1 3110 and transistor M2 3130, respectively.

In FIG. 3A, the bottom represents a P-Substrate (P-SUB 3103), which is commonly found in standard semiconductor silicon substrates. Since transistors M1 3110 and M2 3130 are PMOS transistors, an N-Well (NW 3105) layer is present on the P-SUB 3103, with the Source and Drain (S/D 3104, 3108) located on top of it. In contrast, transistor M3 3170 is an NMOS transistor, so its Source and Drain (S/D 3106) are directly formed on the P-SUB 3103. A polysilicon layer 3101 is used to form the gates of transistors M1 3110, M2 3130, and M3 3170, which together share a common Floating Gate (FG 3102). As shown in FIG. 3A, transistor M1 3110 has a much larger width than transistor M2 3130 and transistor M3 3170 to achieve a strong coupling effect. In this example, transistor M1's width (W1 3120) is 8 times larger than the width of transistors M2 and M3 (W2 3140, W3 3160).

FIG. 3B shows a case where a floating gate FG is connected through metal layer and vias while remaining isolated from any other node. Specifically, metal 1 layer 3209 connects the gate terminals of transistors M1 3210, M3 3270, and M2 3230 to form a single floating gate FG 3202. The vias 3207 connecting the polysilicon layer 3201 and the metal 1 layer 3209 are represented in black. Since transistors M1 3210 and M2 3230 are PMOS transistors, an N-Well 3205 is present on the P-SUB 3203, with the Source and Drain (S/D 3204, 3208) located on top of it. As in FIG. 3B, transistor M3 3270 is in the middle of transistors M1 3210 and M2 3230, and its source and drain (S/D 3206) are directly connected to the P-SUB 3203. Moreover, transistor M3 does not have to be placed between transistors M1 and M2 in view direction 220; it can be placed outside of the transistor M2 or transistor M1.

Thus, as shown in FIGS. 3C and 3D, as long as transistor M1 (3310, 3410), transistor M2 (3330, 3430), and transistor M3 (3370, 3470) share the FG (3302, 3402) through the shared gate of polysilicon layer (3301, 3401) or vias (3307, 3407) connecting the polysilicon layer (3301, 3401) and metal layer (3309, 3409), the position of transistor M3 (3370, 3470) does not need to be fixed.

In FIGS. 3C and 3D, each transistor M3 (3370, 3470) has been placed on the right side of transistor M2 3330 and the left side of transistor M1 3410, respectively.

As in FIG. 3A, in the cases of FIGS. 3B-3D, transistor M1 has a width W that is 8 times larger than that of transistors M2 and M3, which can increase macro area when implementing high-density embedded non-volatile flash memory.

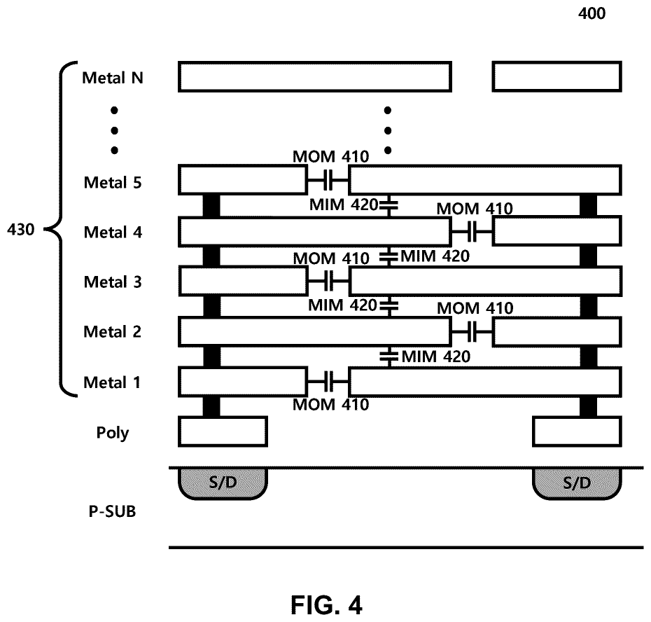

FIG. 4 shows a vertically cut cross-section 400 of common types of metal capacitors used in analog integrated circuits. In FIG. 4, two types of common metal capacitors are illustrated: one is a Metal-Oxide-Metal (MOM 410) capacitor, and the other is a Metal-Insulator-Metal (MIM 420) capacitor. Metal-Oxide-Metal (MOM 410) capacitors are interdigitated, multi-finger capacitors formed by metal layers 430, interlocking like the fingers of two clasped hands. In actual semiconductor circuit design and implementation, multiple layers 430 of metal are used for circuit connections. In this process, MOM 410 capacitors are formed between two adjacent metal lines within the same metal layer, using a dielectric material between two adjacent metal lines such as silicon nitride (Si₃N₄), silicon dioxide (SiO₂), or a high-k dielectric like hafnium oxide (HfO₂). Standard metal wiring lines are used to form the plates of the capacitor, and the required capacitance is generated by the lateral (intralayer) capacitive coupling effect between the plates.

Unlike MOM 410 capacitors, MIM 420 capacitors can be formed between adjacent metal layers 430. As shown in FIG. 4, MIM 420 capacitors can be found between the metal 1 layer and the metal 2 layer, between the metal 2 layer and the metal 3 layer, between the metal 3 layer and the metal 4 layer, and so on. MIM 420 capacitors have a higher capacitance per unit area compared to MOM 410 capacitors and are similar to a parallel plate capacitor where metal plates (electrodes) are separated by an insulating material (dielectric) such as silicon nitride (Si₃N₄), aluminum oxide (Al₂O₃), tantalum pentoxide (Ta₂O₅), or other high-k dielectrics. In newer nodes (with critical dimensions less than 100 nm), integration is done using comb-like MOM 410 structures without additional mask steps, which is made possible by the reduced sizes and spacings. On the other hand, in older commercial nodes, the classical approach of using MIM 420 capacitors is applied, which requires additional mask steps for the deposition of the insulating material and for contacting the neighboring metal layers.

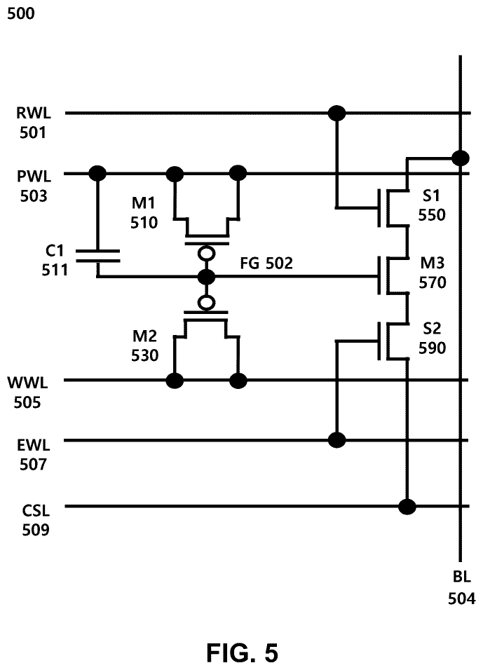

FIG. 5 shows a proposed 5T (five transistors) eFlash memory (embedded flash memory) unit cell 500 schematic using metal capacitor (C1 511). The proposed 5T eFlash memory unit cell 500 in FIG. 5 has the same basic structure as the traditional 5T eFlash memory unit cell 100 in FIG. 1 in terms of transistor connections and signal lines.

However, the proposed memory unit cell 500 includes a metal capacitor C1 511 connected in parallel with transistor M1 510 between the FG 502 node and PWL 503. The floating gate FG 502 in the memory unit cell 500 is capacitively coupled to transistor M1 510 and transistor M2 530 and, it is also connected to the gate of M3 570. The source and drain of transistors M1 510 and M2 530 are connected to PWL 503 and WWL 505, respectively. The drain and source of transistor M3 570 are connected to the source of transistor S1 550 and the drain of transistor S2 590, respectively. The drain of transistor S1 550 is connected to the bit line (BL 504), and its gate receives the RWL 501 signal. The gate of transistor S2 590 receives the EWL 507 signal, and its source is connected to the CSL 509.

As described in FIG. 4, a metal capacitor C1 511 can be implemented using metal lines with multiple metal layers. Metal capacitor C1 511 can support the function of the coupling device (M1 510 transistor) in a logic-compatible eFlash memory unit cell 500, enabling a smaller cell array area by reducing the size of transistor M1 510. Since metal capacitor C1 511 creates a capacitive coupling effect from PWL 503 to the FG 502 node, the size of transistor M1 510 (e.g., width) can be reduced compared to the case where only transistor M1 110 is used without metal capacitor C1 511 in FIG. 1. As a result, the size of the proposed 5T eFlash memory unit cell 500 using a metal capacitor C1 511 can be significantly smaller compared to the memory unit cell 100 without a metal capacitor C1 511. As described in FIG. 1, it can serve as a solution to the issue of increased macro area when implementing high-density embedded non-volatile flash memory, which was caused by the significantly larger size of transistor M1 110 compared to other transistors.

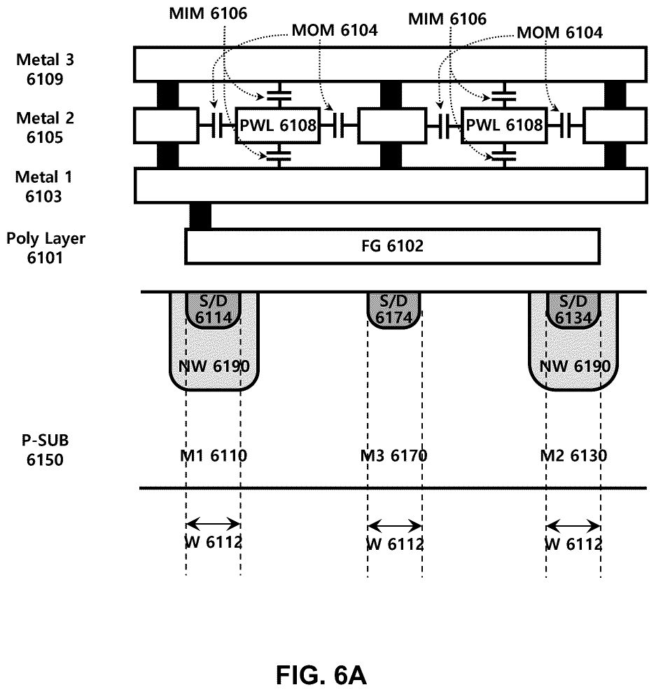

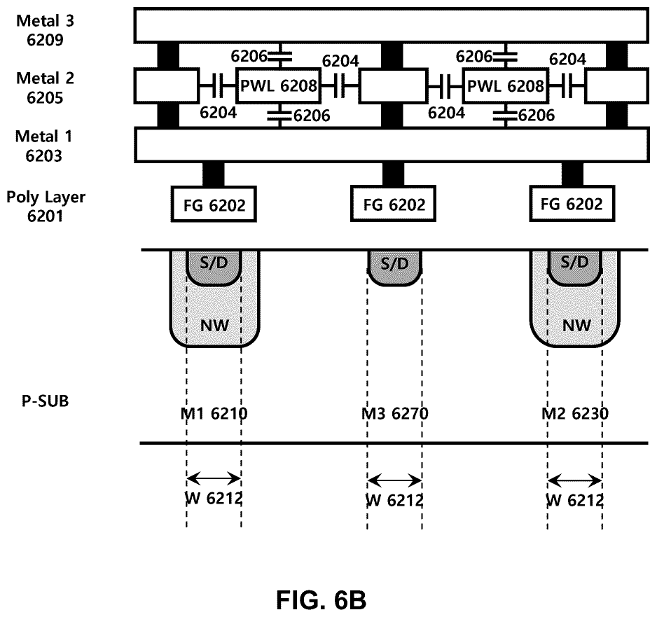

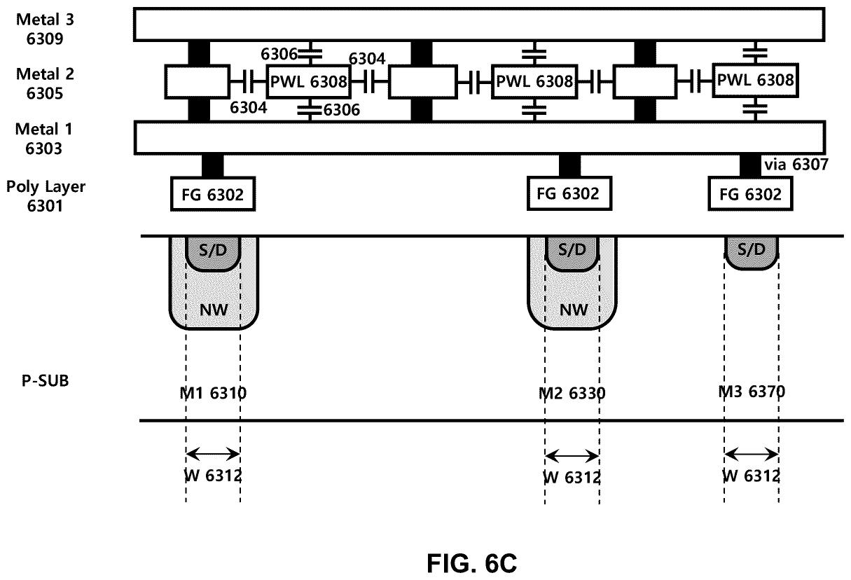

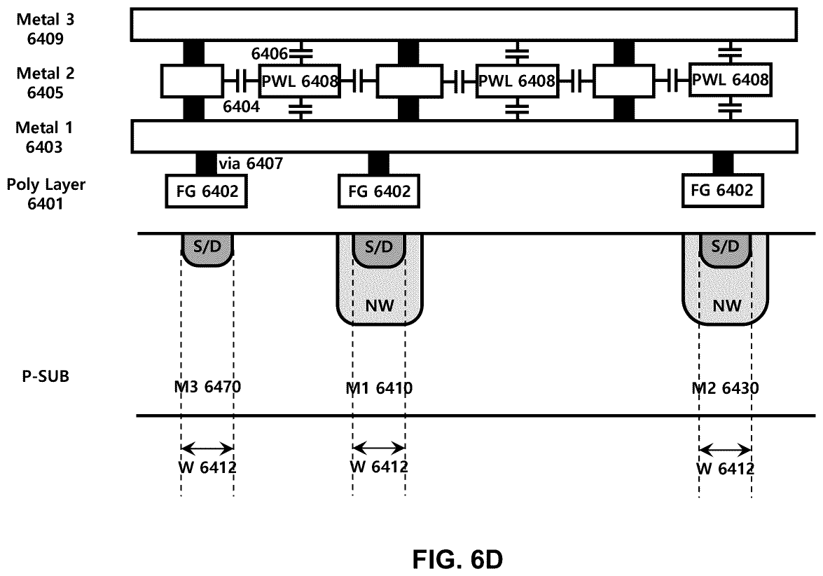

FIGS. 6A-6D show cross-sectional views in the view direction 220 of transistors M1 510, M2 530, M3 570 sharing the floating gate (FG 502) in the proposed 5T eFlash memory unit cell 500 with metal capacitor C1 511 implemented on an actual semiconductor substrate shown in FIG. 5. Each proposed example in FIG. 6A-6D corresponds to its respective traditional example in FIG. 3A-3D. As described in FIGS. 3A-3D, transistors S1 and S2 (not shown), which do not share the FG, can be placed anywhere around transistors M1-M2-M3.

FIG. 6A shows transistors M1-M3-M2 example structure sharing a floating gate FG 6102 on a polysilicon layer 6101, similar to the one shown in FIG. 3A. Furthermore, the floating gate FG 6102 on a poly layer 6101 is connected to a plurality of metal layers (i.e., Metal 1 6103, Metal 2 6105, and Metal 3 6109) according to one embodiment of the present invention.

In one embodiment, MOM capacitors 6104 are formed between two adjacent lateral metal lines (including PWL 6108) on the same metal layer: Metal 2 6105. A dielectric material is filled between two adjacent metal lines, such as silicon nitride (Si₃N₄), silicon dioxide (SiO₂), or a high-k dielectric like hafnium oxide (HfO₂). Standard metal wiring lines are used to form the plates of the capacitor, and the required capacitance is generated by the lateral (intralayer) capacitive coupling effect between the plates.

In another embodiment, MIM capacitors 6106 are also formed between a program word line PWL 6108 and a meal layer Metal 3 6109, as well as between PWL 6108 and a metal layer Metal 1 6103. Although two PWL 6108 lines are illustrated in the example of FIG. 6A, it is to be understood that the number of PWL 6108 lines is not limited thereto and may vary as required by the particular design or application. The metal capacitors, MOM 6104 and MIM 6106 capacitors, are connected in parallel with transistor M1 6110 between the FG 6102 and PWL 6108.

Similar to FIG. 3A, the bottom of FIG. 6A represents a P-Substrate (P-SUB 6150), which is commonly found in standard semiconductor silicon substrates. Since transistor M1 6110 and transistor M2 6130 are PMOS transistors, while transistor M3 6170 is an NMOS transistor, the Source and Drain (S/D 6114, 6134) of transistor M1 6110 and transistor M2 6130 are formed on an N-Well (NW 6190), whereas the Source and Drain (S/D 6174) of transistor M3 6170 are directly formed on the P-SUB 6150. In the case of a traditional 5T eFlash memory unit cell 100, as shown in FIG. 3A, the width (W 3120) of transistor M1 3110 is eight times larger than that of transistor M2 3130 and transistor M3 3170 to achieve a strong coupling effect.

However, in the proposed 5T eFlash memory unit cell 500, as shown in FIG. 6A, the strong coupling effect of the MIM capacitor 6106 and MOM capacitor 6104 positioned in parallel with transistor M1 6110 allows a transistor M1 6110 to have the same width (W 6112) as transistor M2 6130 and transistor M3 6170. The width (W 6112) of transistor M1 6110, reduced to 1/8 compared to FIG. 3A, can greatly facilitate the high-density integration of embedded non-volatile flash memory.

Another example embodiment in FIG. 6B has a structure with the transistor M1-M3-M2 order from left to right which is similar to FIG. 6A. It should be noted, however, unlike FIG. 6A, each transistor (M1 6210, M3 6270, M2 6230) individually possesses a gate region that is part the common Poly Layer 6201, and this poly layer forms the floating gate FG 6202. Further, theses physically distinct gate regions (on the poly layer 6201 for each M1,

M2, M3) are then electrically connected together though Metal 1 6203 layer. Additionally, similar to FIG. 6A, MOM capacitors 6204 and MIM capacitors 6206 are formed by two adjacent metal lines within the same metal layer and stacking a plurality of metal layers: Metal 1 6203, Metal 2 6205, and Metal 3 6209.

These formed metal capacitors (MOM capacitors and MIM capacitors) in parallel with the transistor M1 6210 between the FG 6202 and PWL 6208 result in a strong coupling effect. This result allows transistor M1 6210 to have a width (W 6212) approximately 1/8 of transistor M1 3210 in FIG. 3B, which is the same as the width W 6212 of transistor M2 6230 and transistor M3 6270. This can greatly facilitate the integration of embedded non-volatile flash memory at a high density.

As shown in FIGS. 6C and 6D, it also should be noted that a transistor M3 (6370, 6470) does not need to be positioned between a transistor M1 (6310, 6410) and a transistor M2 (6330, 6430), it can instead be placed outside of the transistor M1 (6310, 6410) and transistor M2 (6330, 6430). The location of the transistor M3 (6370, 6470) is on the right side of the transistor M2 6330 and the left side of the transistor M1 6410, respectively. Even when the transistor M3 (6370, 6470) is placed outside between the transistor M1 (6310, 6410) and the transistor M2 (6330, 6430), it still shares FG (6302, 6402) through the shared gate of the polysilicon layer (6301, 6401) or vias (6307, 6407) connecting the polysilicon layer (6301, 6401) and metal layers. Additionally, MOM (6304, 6404) and MIM (6306, 6406) capacitors, utilizing Metal 1 (6303, 6403), Metal 2 (6305, 6405), and Metal 3 (6309, 6409) layers, are connected in parallel with transistor M1 (6310, 6410) between the FG (6302, 6402) and PWL (6308, 6408). These metal capacitors provide a strong coupling effect, allowing the width (W 6312, 6412) of transistor M1 (6310, 6410) to be reduced to the same size as that of transistor M2 (6330, 6430) and transistor M3 (6370, 6470). This can greatly facilitate the high-density integration of embedded non-volatile flash memory.

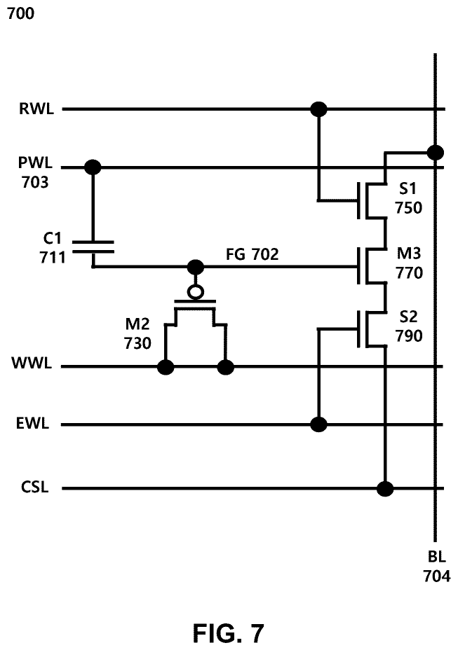

FIG. 7 shows a proposed 4T (four transistors) eFlash memory (Embedded Flash) unit cell 700 schematic using a metal capacitor with a specific size according to some embodiments of the present invention. In FIG. 7, the capacitance of a metal capacitor C1 711 formed between PWL 703 and FG node 702 is proportional to an area of the metal plates of the metal layers for the capacitor C1 711 and inversely proportional to the distance between the metal plates of the metal layers. Therefore, in advanced foundry processes, the space between metal lines on the same metal layer can be smaller, which means that MOM capacitors can achieve higher capacitance.

Referring back to the traditional 5T eFlash memory unit cell 100 in FIG. 1, to achieve a strong coupling effect between FG 102 and PWL 103, transistor M1 110 is required to be approximately eight times wider than transistors M2 130 and M3 170. However, the metal capacitor C1 511, as shown in FIG. 5, connected in parallel with transistor M1 510 between the FG 502 node and PWL 503, can create the strong coupling effect. As a result, the transistor M1 510 can have the same width as transistors M2 530 and M3 570, and still operate as the traditional 5T eFlash memory unit cell 100 in FIG. 1.

As described previously, using advanced foundry processes, as the space between metal lines on the same metal layer becomes smaller, the capacitance of MOM capacitors can increase. As a result, if the metal capacitor C1 711 is capable of meeting the required capacitance for the 5T eFlash unit cell 100 or 500 structure shown in FIG. 1 or FIG. 5, a strong coupling effect can be achieved between the FG 702 node and PWL 703 due to the large capacitance of the metal capacitor C1 711, even without the M1 transistor. The proposed 4T eFlash memory unit cell 700 schematic in FIG. 7, compared to FIG. 5, shows that transistors M2 730, M3 770, S1 750, and S2 790 have the same structure, but the transistor M1 has been removed, leaving only the metal capacitor C1 711. By eliminating transistor M1, the area previously occupied by transistor M1 on the semiconductor substrate can be removed when implementing the eFlash memory unit cell 700. This effectively addresses the issue of increased macro area that arose when implementing high-density embedded non-volatile flash memory using the traditional 5T eFlash memory unit cell 100.

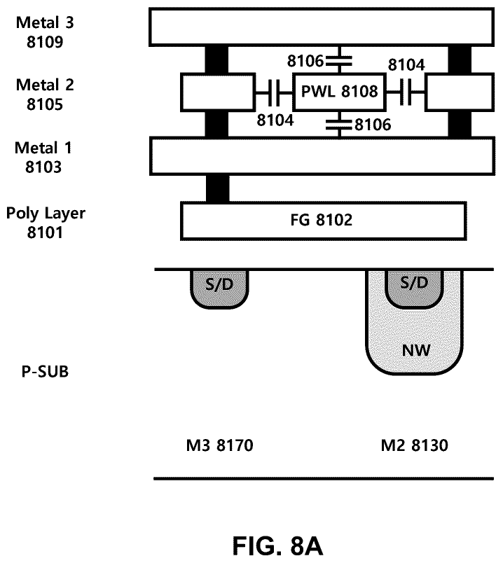

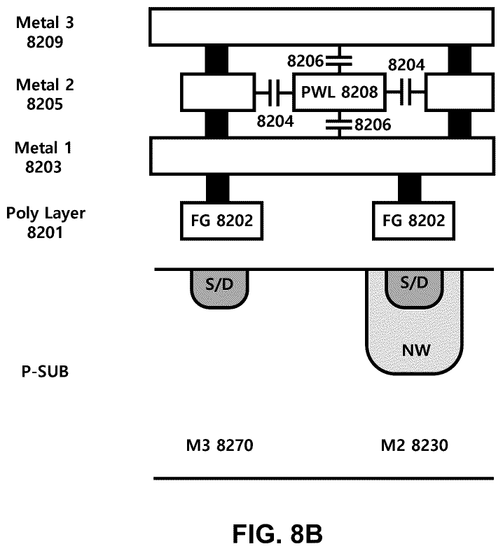

FIGS. 8A-8B show cross-sectional views of transistors M2, M3, which share the floating gate with a metal capacitor C1 according to the proposed 4T eFlash memory unit cell. As previously described in FIGS. 3A-3D and FIGS. 6A-6D, the transistors S1 and S2 (not shown), which do not share the FG 702, can be placed anywhere near transistors M2 and M3.

In FIG. 8A a floating gate FG 8102 on the polysilicon layer 8101 is connected to metal layers Metal 1 8103, Metal 2 8105, and Metal 3 8109, forming capacitors MOM 8104 and MIM 8106 as described in FIG. 6A. However, as compared to that of FIG. 6A, FIG. 8A shows only the cross-sections of transistors M2 8130 and M3 8170, since transistor M1 has been removed. Furthermore, the number of metal capacitors (MOM 8104 and MIM 8106) in FIG. 8A has been reduced as compared to that of FIG. 6A. Metal capacitors achieve higher capacitance as a result of advanced foundry processes, as described above, allowing a strong coupling effect between a floating-gated FG 8102 and a program word line PWL 8108. This results in fewer metal capacitors, enabling the removal of transistor M1.

In an example of FIG. 8B, as compared to that of FIG. 8A, floating gates 8201 for transistors M2 8230 and M3 8270 are not physically integrated together, but they are connected through a metal layer Metal 1 8203, which allows them to share the FG 8202. Additionally, each floating gate of the transistors M2 8230, M3 8270 on the poly layer 8201 is directly connected to the metal layers: Metal 1 8203, Metal 2 8205, and Metal 3 8209. The MOM 8204 and MIM 8206 capacitors act as metal capacitor C1 711, causing a strong coupling effect between the FG 8202 and PWL 8208. Despite the removal of transistor M1, this 4T eFlash memory unit cell 100 operates the same way as the traditional 5T eFlash memory unit cell 100. Also, with advanced foundry processes, it is possible to obtain a metal capacitor C1 711 with higher capacitance, which can enhance the coupling effect between the FG 8202 and PWL 8208, even with fewer metal capacitors.

As illustrated in FIGS. 8A and 8B, the high-capacitance metal capacitors make it possible to remove the transistor M1 while maintaining the same functionality as the traditional 5T eFlash memory unit cell 100. This reduction in unit memory cell size significantly decreases the total area of the cell array, effectively addressing the increased macro area issue encountered when implementing high-density embedded non-volatile flash memory with the traditional ST eFlash memory unit cell 100.

What is claimed is:

1. A nonvolatile memory unit cell comprising:
a P-type substrate;
a set of one or more P-type transistors with floating gates that store a charge, each having an active drain and source region on an N-well doped on the P-type substrate;
one N-type transistor sharing the floating gate of the one or more P-type transistors, with active drain and source regions doped on the P-type substrate;
a polysilicon layer above the gate regions of the P-type and N-type transistors;
a plurality of control lines as electrical pathways used to apply voltages to the gates, source, and drains of the transistors for operation, including a programming word line; and
a plurality of metal layers deposited above the polysilicon layer,
wherein a main metal layer is configured with a plurality of metal plates that are spaced apart with one or more predefined intervals forming a parallel-plate structure in a lateral direction; and
wherein the main metal layer forms a parallel plate structure in a horizontal direction with at least one parallel metal layer, which is directly facing the main metal layer and separated from the main metal layer by a dielectric insulating layer.

2. A nonvolatile memory unit cell of claim 1, wherein the main metal layer is placed between a pair of parallel metal layers and insulated by dielectric insulating layers that separate the main metal layer from each of the pair of parallel metal layers.

3. The nonvolatile memory unit cell of claim 1, wherein a number of the set of one or more P-type transistors is determined based on capacitance created by the main metal layer and the at least one parallel metal layer.

4. The nonvolatile memory unit cell of claim 3, wherein the set of P-type transistors with floating gates consists of a pair of P-type transistors and a size of the active drain/source regions of a first transistor of the pair of P-type transistors is determined based on the capacitance created by the main metal layer and the at least one parallel metal layer.

5. The nonvolatile memory unit cell of claim 2, wherein the polysilicon layer is (1) a layer of polycrystalline silicon as gate material of the one or more P-type transistors and the N-type transistor and (2) electrically insulated from the active regions of the one or more P-type transistors and the N-type transistor by a tunnel oxide with predefined thickness.

6. The nonvolatile memory unit cell of claim 5, wherein a first of the pair of parallel metal layers is a metal plate parallel to the polysilicon layer in a horizontal direction of the memory unit cell and spaced apart and isolated from the polysilicon layer by a first interlayer dielectric with predefined thickness.

7. The nonvolatile memory unit cell of claim 6, wherein a length of the first parallel metal layer is determined based on an area of the one or more P-type transistors on the N-well doped on the P-type substrate and the N-type transistor in a horizontal direction of the memory unit cell.

8. The nonvolatile memory unit cell of claim 6, wherein the first parallel metal layer further comprises one or more vias connecting the first parallel metal layer to the polysilicon layer.

9. The nonvolatile memory unit cell of claim 1, where the main metal layer is spaced apart and isolated from the first parallel metal layer by a second interlayer dielectric with predefined thickness.

10. The nonvolatile memory unit cell of claim 9, wherein the main metal layer further comprises the programming word line with a horizontal width allowing each programming word line to be placed between a pair of the metal plates, forming the parallel-plate structure to create capacitance in the lateral direction.

11. The nonvolatile memory unit cell of claim 10, wherein a gap between the metal plate and the programming word line is filled with a standard intermetal dielectric.

12. The nonvolatile memory unit cell of claim 11, wherein the main metal layer further comprises a first group of vias connecting the main metal layer to the first parallel metal layer.

13. The nonvolatile memory unit cell of claim 2, wherein a second of the pair of parallel metal layers is a metal plate parallel to the main metal layer and spaced apart from the main metal layer by a third interlayer dielectric with predefined thickness, forming a parallel plate structure between the second parallel metal layer and the one or more programming word line.

14. The nonvolatile memory unit cell of claim 13, wherein the main metal layer further comprises a second group of vias connecting the main metal layer to the second parallel metal layer.

15. The nonvolatile memory unit cell of claim 1, further comprising: a pair of N-type select transistors connected to the N-type transistor in series.

16. The nonvolatile memory unit cell of claim 15, wherein a first of the pair of N-type select transistors has a gate directly connected to a read word line (RWL) and a second of the pair of N-type select transistors has a gate directly connected to an erase word line (EWL).

17. The nonvolatile memory unit cell of claim 16, wherein the first N-type select transistor has a drain directly connected to a bit line (BL) and the second N-type select transistor has a source directly connected to a common source line (CSL) for carrying a signal for operating the nonvolatile memory unit cell.

18. The nonvolatile memory unit cell of claim 17, wherein the first N-type select transistor and the N-type transistor share a common active drain/source region and the second N-type select transistor and the N-type transistor share a common drain/source region.
